(19) United States
(12) Patent Application Publication
(10) Pub. No.: US 2020/0007084 A1
(43) Pub. Date: Jan. 2, 2020

(54) LOW NOISE BLOCK CONVERTER INTEGRATED CIRCUIT

(71) Applicant: ALi Corporation, Hsinchu (TW)

(72) Inventors: CEDRIC LAMBERTET, Geneva (CH); Christian Eichrodt, Geneva (CH); Fabio Epifano, Geneva (CH); Claude-Alain Gobet, Geneva (CH); Alfredo Bautista, Geneva (CH); Jian-Xin Li, Shanghai (CN)

(73) Assignee: ALi Corporation, Hsinchu (TW)

(21) Appl. No.: 16/421,285

(22) Filed: May 23, 2019

Related U.S. Application Data
(60) Provisional application No. 62/691,615, filed on Jun. 29, 2018.

(51) Int. Cl. H03D 7/16; H03D 7/18; H04N 7/20; H04H 40/90

(52) U.S. Cl. CPC H03D 7/165; H04H 40/90; H04N 7/20; H03D 7/18

(57) ABSTRACT

The disclosure provided a low noise block converter for converting RF signal received from a satellite into IF signal, where the image rejection of the RF signal is performed in two stages through a low noise amplifier (LNA) integrated circuit (IC). The disclosure reduced the number of discrete components by integrating electronic components onto one integrated circuit (or chip), and at the same, improves the noise figure of the LNB converter. The LNB IC comprises LNA circuits, RF path selector, and signal downconverter, where the image rejection is performed by a combination of the LNA circuits and the signal downconverter.

### CROSS-REFERENCE TO RELATED APPLICATION

This application claims the priority benefit of U.S. provisional application Ser. No. 62/691,615, filed on Jun. 29, 2018. The entirety of the above-mentioned patent application is hereby incorporated by reference herein and made a part of this specification. Precise

### BACKGROUND

### Technical Field

The invention relates a low noise converter, and more particularly, relates to a low noise downconverter being integrated into a single chip.

### Description of Related Art

In a satellite broadcasting system, radio frequency (RF) signals are being broadcasted from a satellite and received by an antenna. At the reception end of the broadcast system, a low noise block (LNB) converter (may also be referred to as LNB downconverter) is used to perform low-noise amplification and frequency conversion, where a RF signal transmitted from the satellite (e.g., 10.7 GHz-12.75 GHz) is amplified and converted to an intermediate frequency (IF) signal (e.g., 1 GHz). The IF signal is then supplied to a set-top-box (STB), also referred to as a tuner and eventually reaches to a television or any monitor (image displaying electronic device) for displaying the information embedded in the RF signal.

The LNB converter is installed at a reflection focal point of a satellite receiving antenna. The size of the LNB converter is generally small, however, many discrete polarizations are required for processing the RF signal transmitted from the satellite. Furthermore, the image spectrum of the RF signal is rejected (image rejection) in order to allow the signal demodulation. Many implementations of the image rejection are done by filters implemented at printed circuit board (PCB) level while maintaining good noise figures (NF). For example, low-noise amplifiers (LNA) are often used between probes that receive the RF signal and the frequency conversion polarizations. For the purpose of good noise to signal ratio, discrete LNA are often used. However, PCB polarizations are large and add complexity to the LNB converter.

Nothing herein should be construed as an admission of knowledge in the prior art of any portion of the present invention. Furthermore, citation or identification of any document in this application is not an admission that such document is available as prior art to the present invention, or that any reference forms a part of the common general knowledge in the art.

### SUMMARY

The disclosure is directed to a low-noise block converter being integrated on an integrated circuit that minimized the usage of discrete electronic polarization at printed-circuit board (PCB) level, and at the same time, the low-noise block maintains a good noise figure with on-chip polarizations.

In some exemplary embodiments, a low noise block (LNB) converter is integrated in an integrated chip. The LNB converter includes a low noise amplifier (LNA) integrated circuit (IC) including a first low noise amplification circuit, a second low noise amplification circuit, a RF path selector, and a signal downconverter. The LNB IC includes a first pin and a second pin that are directly or indirectly coupled to an antenna for receiving first and second polarizations of the RF signal respectively. The first low noise amplification circuit is coupled to the first pin for receiving the first polarization signal and configured to remove partially image signal from the first polarization signal and generate a first amplified and filtered polarization signal. The second low noise amplification circuit is coupled to the second pin for receiving the second polarization signal from the antenna and configured to remove partially the image signal from the second polarization signal and generate a second amplified and filtered polarization signal. The RF path selector is coupled to the first and second amplification circuits for directing the path of the first and second amplified and filtered polarization signals. In addition, the signal downconverter is coupled between the RF path selector and a first output pin for partially removing the remaining image signal of the RF signal after the first and second amplification circuits.

In some exemplary embodiments, a satellite receiving system includes an antenna, a set-top-box, and a LNB converter coupled therebetween. The LNB converter includes an LNB IC having the capability of performing image rejection through the amplification circuit and signal downconverter integrated thereon.

To make the above features and advantages of the disclosure more comprehensible, several embodiments accompanied with drawings are described in detail as follows.

It should be understood, however, that this summary may not contain all of the aspects and embodiments of the present invention, is not meant to be limiting or restrictive in any manner, and that the invention as disclosed herein is and will be understood by those of ordinary skill in the art to encompass obvious improvements and modifications thereto.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 illustrates a block diagram of an LNB converter according to some exemplary embodiment of the disclosure.

FIG. 2 is a graph that shows the received RF signal according to some exemplary embodiment of the disclosure.

FIG. 3 is a block diagram of the LNA circuit according to some exemplary embodiments of the disclosure.

FIG. 4 is a block diagram of an LNA circuit according to some exemplary embodiments of the disclosure.

FIG. 5 is a diagram illustrating a signal downconverter according to some exemplary embodiments of the disclosure.

FIG. 6 is a block diagram illustrating a LNB converter according to some exemplary embodiments of the disclosure.

FIG. 7 is a block diagram illustrating a twin LNB converter according to some exemplary embodiments of the disclosure.

FIG. 8 is a block diagram illustrating a LNB converter according to some exemplary embodiments of the disclosure.

FIG. 9 is a block diagram illustrating a satellite receiving system according to some exemplary embodiments of the disclosure.

### DESCRIPTION OF THE EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

The disclosure decreased the number of discrete components by integrating the necessary components onto one integrated circuit (chip). Specifically, the disclosure performs the image rejection on the received RF signal by a combination of the on-chip LNA circuits and the signal downconverter, i.e., two stages image rejection. The image spectrum of the RF signal is first filtered by an image rejection filter build-in the on-chip LNA circuit for removing part of the image spectrum (image signal). At the second stage of the image rejection, the image spectrum of the RF signal is further attenuated by the signal downconverter.

In the communication system, signals or information are transmitted through radio wave which is also called radio frequency (RF) signal, where information is embedded in different polarizations of the radio wave. Generally, information is transmitted through horizontal polarization and vertical polarization of the RF signal. A satellite antenna reflects the received RF signal to a focal point where a feed horn having two probes is disposed. The probes are arranged for receiving horizontal polarized RF signal and vertical polarized RF signal, respectively. The horizontal polarized RF signal and the vertical polarized RF signal are transmitted to the LNB converter for signal amplification, image spectrum filtering, frequency conversation, etc. The polarized RF signals are feed into low-noise amplifiers (LNA) for signal amplification. After signal amplification, the image spectrum of the amplified RF signals is filtered by using band pass filter. Then, the amplified and filtered signals are transmitted to a signal converter to perform a frequency conversion for down converting the RF signal to an acceptable frequency range for a set-top-box (STB) or tuner. In conventional LNB converter, the LNAs, the band pass filter and the signal converter are discrete polarizations.

The disclosure integrates the discrete polarizations of the low-noise block (LNB) converter onto one chip that greatly decrease the area taken by the discrete polarization, and at the same time, improve the noise figure of the LNB converter. In some exemplary embodiments, the integration of the discrete polarizations of LNB converter is referring to that one integrated circuit (chip) is designed or configured to achieve a capability of the LNB converter with discrete polarizations. Signal amplification or process that used to be performed by the external discrete polarizations is now achieved by the new chip designed to meet the LNB NF requirements without the discrete polarizations of LNB. As compared to PCB, space is important with chip designs. In other words, while the discrete polarizations may take up areas on the PCB, the design of the chip may not have that kind of space. Thus, the design of the chip would be structurally different but achieving the same function and requirements as compared to the discrete polarizations disposed on the PCB. By integrating the discrete polarizations onto one chip, the pinout requirement of the chip is decreased since external transistors or polarizations are decreased. Furthermore, area taken by discrete polarization is also reduced.

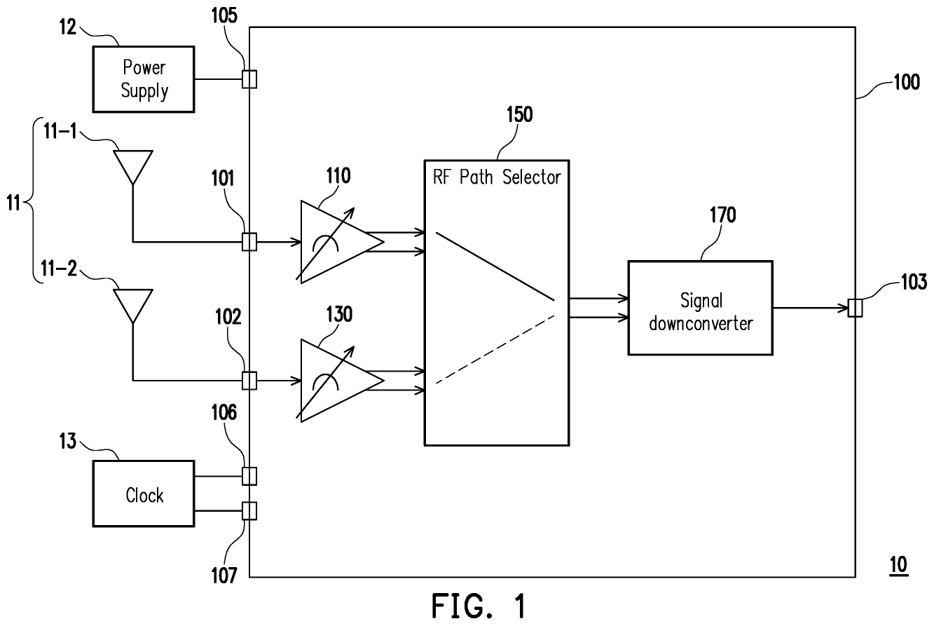

FIG. 1 illustrates a block diagram of an LNB converter 10 according to some exemplary embodiment of the disclosure. With reference to FIG. 1, the LNB converter 10 includes a LNB integrated circuit (IC) 100. The LNB IC 100 includes a first LNA circuit 110, a second LNA circuit 130, a RF path selector 150, and a signal downconverter 170. The disclosure may also refer the first and second LNA circuits 110, 130 as the first and second on-chip LNA circuits 110, 130. The first LNA circuit 110 is coupled between a first pin 101 (input) of the LNB IC 100 and the RF path selector 150 for receiving a first polarization of the RF signal. The second LNA circuit 130 is coupled between a second pin 102 (input) of the LNB IC 100 and the RF path selector 150 for receiving a second polarization of the RF signal. The signal downconverter 170 is coupled between the RF path selector 150 and an output pin 103 of the LNB IC 100.

In the exemplary embodiment, the RF signal is received through an antenna 11, where the first and second polarizations (e.g., horizontal and vertical polarizations) of the RF signal are respectively transmitted to the first pin 101 and the second pin 102 of the LNB IC 100. The first and second polarization of the RF signal may also be referred to as a first polarized signal and a second polarized signal. In the exemplary embodiment, the first and second polarizations of the RF signal may be directly or indirectly coupled to the first and second pins 101, 102. The first polarization of the RF signal is transmitted to the first LNA circuit 110 for signal amplification through the first pin 101. The second polarization of the RF signal is transmitted to the second LNA circuit 130 for signal amplification through the second pin 102. In addition to the signal amplification, the first and second LNA circuits 110, 130 are also configured to have a function of the image rejection for removing partial image spectrum of the RF signal (in the first and second polarizations.) The image rejection of the first and second LNA circuits 110, 130 would be described in detail later.

Then, the amplified and filtered RF signal that is in differential form is transmitted to the RF path selector 150, which allows a selection of the first polarization or the second polarization of the RF signal. In the exemplary embodiment, the RF path selector may be a multiplexer or a combiner that has similar function as a Wilkinson combiner. However, the exemplary embodiment is not intended to limit the implementation of the RF path selector 150, any circuitry that enables the selection of signal path may be utilized.

Next, the selected RF signal is transmitted from the RF path selector 150 to the signal downconverter 170. The signal downconverter 170 is configured to down convert the received RF signal to the intermediate frequency (IF) signal and the image spectrum of the RF signal may be further attenuated or suppressed.

In the following, the operation of the LNB converter for processing of the received RF signal would be described in detail.

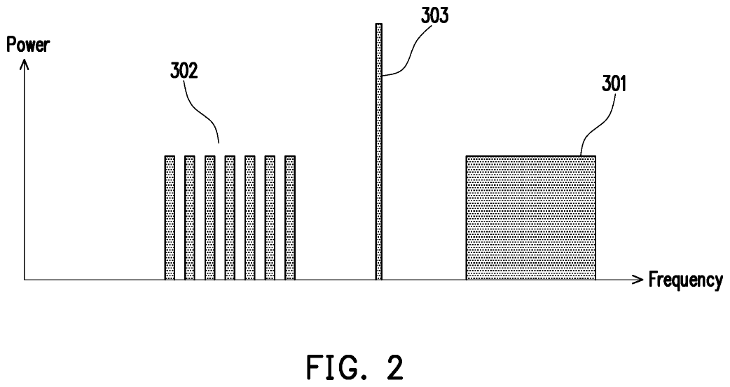

In the received RF signal, a phenomenon of image spectrum may be seen, and therefore, image rejection is required to filter out the unwanted section of the RF signal and obtain the wanted section of the RF signal. FIG. 2 is a graph that shows the received RF signal according to some exemplary embodiment of the disclosure. With reference to FIG. 2, the wanted signal 301 and the unwanted signal 302 are centered around a local frequency 303 of a local oscillator. There are various ways to reject the image spectrum (image rejection). For one, the image rejection can be done by using a complex mixer. Other way to perform image rejection is to filter the unwanted frequency by using a band pass filter or image filter before the down conversion. In the exemplary embodiment, the image rejection is achieved by using both method above, where the complex mixer and filter (with image rejection filter) are implemented on the LNB IC for rejecting the unwanted image spectrum of the received RF signal.

In the exemplary embodiment, the image rejection is performed in two stages. Partial image spectrum may be rejected at LNA stage, where the received RF signal is amplified. Secondly, the remaining image spectrum may be further attenuated at the signal downconverter 170. In one of the exemplary embodiments, the image rejection is obtained by a combination of a tunable band-pass RF amplifier transfer function and a Hartley image-rejection downconverter. The image rejection of the exemplary embodiment would be described in detail below.

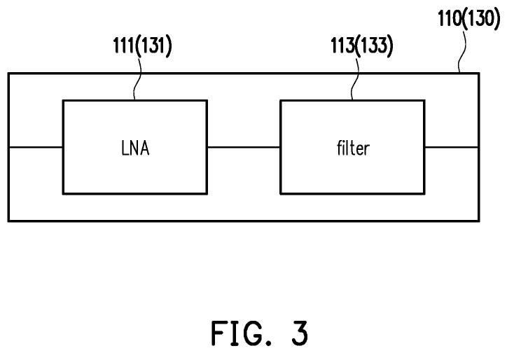

FIG. 3 is a block diagram of the LNA circuit 110, 130 according to some exemplary embodiments of the disclosure. In the exemplary embodiment, the LNA circuits 110, 130 are respectively configured to perform signal amplification and image rejection. With reference to FIG. 3, the LNA 110 includes a LNA 111 and an image rejection filter 113. The LNA 111 is coupled to the first pin 101 for amplifying the first polarization of the RF signal. Next, the first polarization of the RF signal is filtered by the filter 113 for removing part of the image spectrum (partial image rejection.) In the exemplary embodiment, the LNA 111 is based on cascade common source LNAs with inductive degeneration and the image rejection filter 113 may be a tunable band pass filter.

In the exemplary embodiment, the LNA 111 may include various combination of transistors, capacitors, resistors, inductors, etc. that are arranged for amplifying and filtering the received RF signal while maintaining a good noise figure. Since the discrete off-chip LNA is removed and the RF signal is being directly feed to the on-chip LNA circuit 110 (130), the transistors and inductors that are used to implement the on-chip LNA circuit 110 (130) are designed to have high quality factor.

In the exemplary embodiment, the inductors of the LNA circuits 110 (130) may be silicon inductors. In some exemplary embodiments, the inductors of the LNA circuits 110 (130) may be implemented using bonding wires which are better in quality factor as compared to the silicon inductors. The LNA circuit 130 for receiving another polarization of RF wave would have a similar structure for amplifying the second polarization of the RF signal, and thus the description thereof is not repeated here.

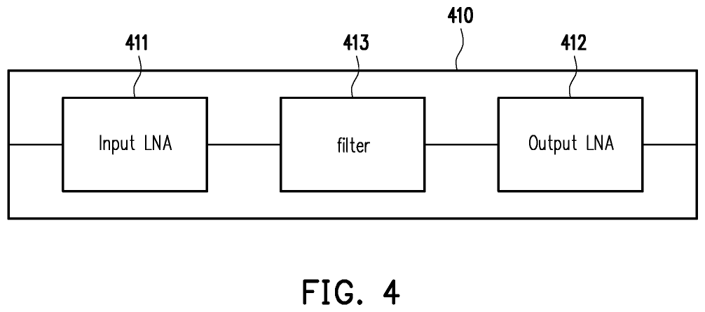

FIG. 4 is a block diagram of an LNA circuit according to some exemplary embodiments of the disclosure. In the exemplary embodiment, the LNA circuit 410 is a two stage LNA that includes an input stage LNA 411 and an output stage LNA 412, and an image rejection filter 413 coupled between the input and output stage LNAs 411, 412.

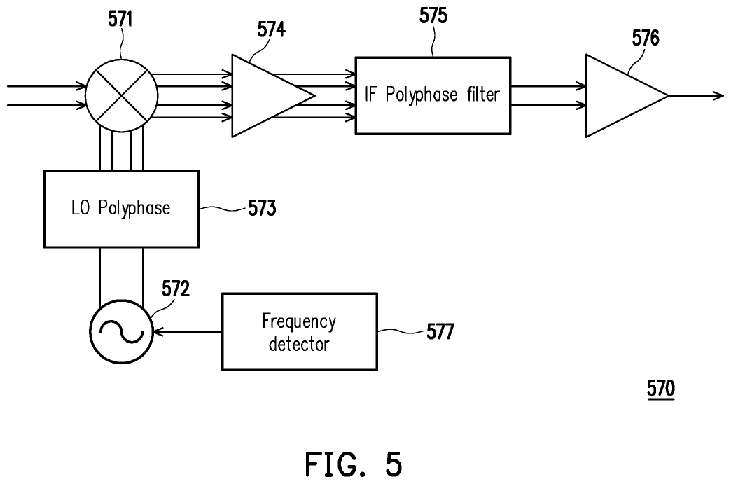

As described above, the image rejection of the LNB IC 100 is further achieved by using the signal downconverter 170, where the image spectrum is further attenuated in addition to the frequency conversion. FIG. 5 is a diagram illustrating a signal downconverter 570 according to some exemplary embodiments of the disclosure. In the exemplary embodiments, the signal downconverter 570 includes a complex mixer 571, a local oscillator 572, a local oscillator polyphase converter 573, a first IF amplifier 574, and an IF polyphase filter 575, and a second IF amplifier 576. The RF differential signal selected by the RF path selector 150 is input to the complex mixer 571, where the complex mixer 571 mixes the RF differential signal with a local frequency provided by the local oscillator 572. The local polyphase unit 573 converts the local frequency into complex signal, where the local frequency is converted into four different phases, which are 0, 180, 90, and 270 degrees. Then, the local frequency is mixed with the RF differential signal received from the RF path selector 150, so as to convert the RF differential signal into IF differential signals.

Next, the IF differential signals are input to the first IF amplifier 574 for signal amplification, and then the IF polyphase filter 575 for generating IF signals. The output of the IF polyphase filter 575 is coupled to the second IF amplifier 576. In the exemplary embodiment, the signal downconverter partially removes the image spectrum of the RF signal by using the complex mixer 571 and IF polyphase filter 575, where the image spectrum of the received RF signal is attenuated (suppressed.) In other words, the IF polyphase filter 575 further remove the image signal remained from the image rejection filter 413. The second IF amplifier 576 amplifies the IF signal having the image spectrum rejected through the LNA circuits and the signal downconverter.

In some exemplary embodiments of the disclosure, the signal downconverter 570 may further include a frequency detector 577. The frequency detector 577 is coupled to the local oscillator 572 for monitoring the received first and second polarization signals as to detect the presence of a signal at a specific frequency, for example 22 kHz. When the specific frequency is detected, a control signal is transmitted to the local oscillator 572 as to select (or change) the local oscillation frequency used for mixing the first or second amplified and filtered polarization signal based on the detection of the presence of the signal at the specific frequency (e.g., 22 kHz).

Based on the circuit structure described above, the image rejection is achieved by a combination of the on-chip LNA circuits 110, 130 and the signal downconverter 170. In detail, the image spectrum of the RF signal is first filtered by an image rejection filter build-in the on-chip LNA circuit. At the second stage of the image rejection, the image spectrum of the RF signal is further attenuated by the signal downconverter having a complex mixer and polyphase filter.

In the design of integrated circuit, an electrostatic discharge (ESD) protection circuit is disposed or directly connected to an input pin for protecting the integrated circuit from any electrostatic discharge. An ESD inductor may be coupled to the input pin (e.g., the first and second pins 101, 102 in series and between the input pin and the ESD protection circuit). In some exemplary embodiments, the ESD inductor is a wire bonding inductor for further enhance the filtering capability of the LNA circuits 110, 130.

Referring back to FIG. 1, the LNB IC 100 further includes a third pin 105 coupled to a power supply 12 for receiving voltage from the power supply 12 as to power the LNB IC 100. The LNB IC 100 also includes a fourth pin 106 and a fifth pin 107 for receiving clock signal from a clock 13 which may be a crystal.

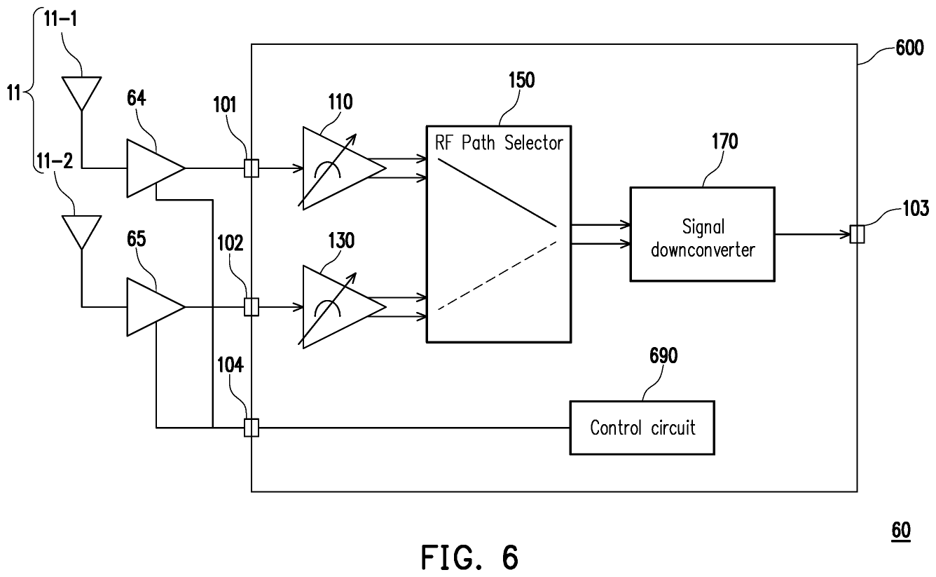

FIG. 6 is a block diagram illustrating a LNB converter 60 according to some exemplary embodiments of the disclosure. With reference to FIG. 6, a first off-chip amplifier 64 and a second off-chip amplifier 65 may be respectively added between the antenna 11 and each of the first and second pins 101, 102 of a LNB IC 600. The LNB IC 600 includes the first and second LNA circuits 110, 130, the RF path selector 150, a signal downconverter 170. The LNB IC 600 of the exemplary embodiment further includes a control circuit 690 and a sixth pin 604 coupled to the control circuit 690. The control circuit 690 is coupled to the first and second off-chip amplifiers 64, 65 through the sixth pin 604 and configured to control the first and second off-chip amplifiers 64, 65. The off-chip amplifiers 64, 65 add sufficient gain before the LNB IC 600 to enhance the LNB noise figure requirement. For example, the noise figure may be less than 2 dB without the off-chip amplifiers. With the off-chip amplifier 64, 65 to add more gain before the LNB IC 100, the noise figure can be greatly improved to 0.6 dB or less.

In the exemplary embodiment, the control circuit 690 may be a processor having logic circuit that is configured to perform the desired functions for controlling the off-chip amplifiers. However, the disclosure is not intended to limit the implementation of the control circuit.

Although two off-chip amplifiers are added to the LNB converter 60, as compared to conventional LNB converter, the number of discrete polarizations is still reduced. Since the LNA circuit is integrated onto one integrated circuit (or chip), the improvement of the noise figure may be achieved by adding one off-chip amplifier on each path of the RF signal. In other words, the LNB converter 60 would only require 2 off-chip amplifiers, whereas the conventional LNB converter would require at least 3 external amplifiers in total.

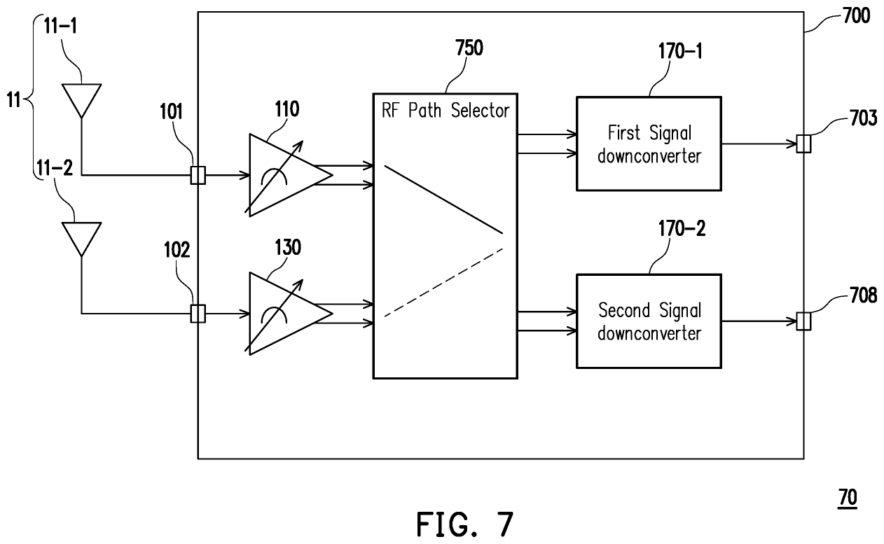

FIG. 7 is a block diagram illustrating a twin LNB downconverter 70 according to some exemplary embodiments of the disclosure. The twin LNB downconverter 70 greatly reduces the number of discrete polarizations as compared to the conventional twin LNB downconverter. Conventionally, each of the polarized signals would require two stage off-chip RF amplifier and band pass filter. Furthermore, the pinout requirement would increase since each RF amplifier would require a control pinout coupled to a control circuit. In the exemplary embodiment, the twin LNB downconverter 70 includes a LNB IC 700 directly or indirectly connected to the probes 11-1, 11-2 of the antenna 11 for receiving a first polarized signal and a second polarized signal. In the exemplary embodiment, the LNB IC 700 includes the first LNA circuit 110, the second LNB circuit 130, a RF path selector 750, a first signal downconverter 170-1 and a second downconverter 170-2.

Similar to the exemplary embodiment illustrated in FIG. 1, the number of the discrete polarizations is reduced by implementing the on-chip LNA circuits 110, 130.

Image rejection of the RF signal is achieved by a combination of on-chip LNA circuits and the complex mixer in the signal downconverter. With reference to FIG. 7, the first and second polarized signals are coupled to the first and second LNA circuits 110, 130 through the first and second pins 101, 102 of the LNB IC 700. The first on-chip LNA circuit 110 amplifies the first polarized signal and partially removes the image spectrum from the first polarized signal. The second on-chip LNA circuit 130 amplifies the second polarized signal and partially removes the image spectrum from the second polarized signal. The implementation of the first and second on-chip LNA circuits 110, 130 is similar to the embodiment illustrated in FIG. 1, and thus the detail description would not be repeated here. Afterward, the output of the first and second on-chip LNA circuit 110, 130 is transmitted to the RF path selector 750 for signal selection and routing. The RF path selector 750 may be 2 inputs and 2 output multiplexer or an RF cross-mux, where each of the first and second polarized signals may be selected as output for a first output pin 703 and a second output pin 708.

The first and second signal downconverter 170-1 and 170-2 are respectively coupled to the first and second output pins 703, 708 of the LNB IC 700 for output IF signals. The implementation of each of the first and second signal downconverter 170-1, 170-2 is similar to the exemplary embodiments illustrated in FIG. 1 and FIG. 5, and thus the detail of which would not be repeated here.

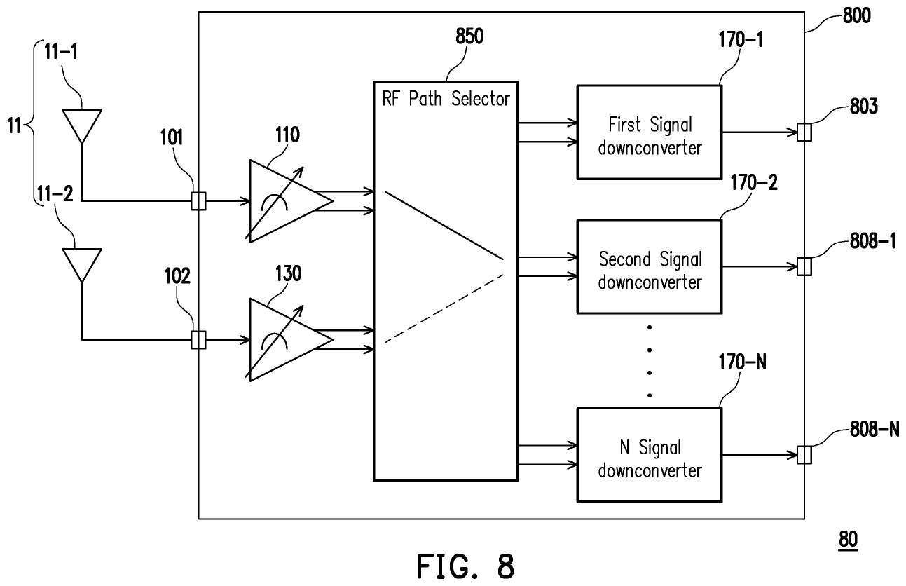

FIG. 8 is a block diagram illustrating a LNB converter according to some exemplary embodiments of the disclosure. As compared to FIG. 7, the LNB converter 80 shown in FIG. 8 includes N signal pathways where N is integer larger than 2. RF signal may be received by the antenna 11 (11-1, 11-2) and being directly or indirectly coupled to a LNB IC 800. The LNA circuits 110, 130 receives RF signal from the antenna 11 (11-1, 11-2) through input pins (101, 102) and passes the received RF signal to a RF path selector 850 after signal amplification, image rejection, etc. In the exemplary embodiment, the RF path selector 850 may be a 2-to-N multiplexer, so as to feed the received RF signal to the N signal downconverters 170-1-170-N coupled between the RF path selector 850 and the output pins (803, 808-1 to 808-N).

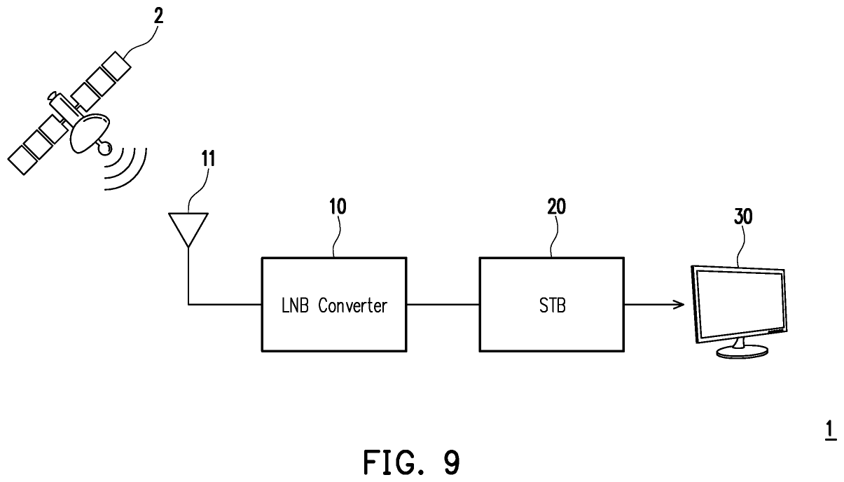

FIG. 9 is a block diagram illustrating a satellite receiving system according to some exemplary embodiments of the disclosure. The satellite receiving system includes an antenna 11, a set-top-box (STB) 20, and a LNB converter 10 connected therebetween. The antenna 11 receives radio wave signal (RF signal) from a satellite 2. The antenna contains probes that respectively receive horizontal and vertical polarization signals of the RF signal. The horizontal and vertical polarization signals are respectively input to the LNB converter 10 for signal processing (e.g., signal amplification, filtering, conversion, etc.) After processing, the LNB converter 10 outputs IF signal that is down converted from the RF signal to the STB 20, where the STB 20 process the IF signal and convert the IF signal into a format for displaying information or data carried by the RF signal on a monitor 30.

In summary, the exemplary embodiments described above depicted a LNB converter integrating LNA, RF path selector, and signal downconverter onto one chip, i.e., a LNB IC has the capability of rejecting image spectrum of the RF signal in two stages. Due to the integrated circuit design, the number of discrete polarizations is greatly reduced, and at the same time, the image rejection is achieved by a combination of the on-chip LNA circuits and the signal downconverter. In detail, the image spectrum of the RF signal is first filtered by an image rejection filter build-in the on-chip LNA circuit for removing part of the image spectrum. At the second stage of the image rejection, the image spectrum of the RF signal is further attenuated by the signal downconverter.

Although the present invention has been described with reference to the above embodiments, it will be apparent to one of ordinary skill in the art that modifications to the described embodiments may be made without departing from the spirit of the invention. Accordingly, the scope of the invention will be defined by the attached claims and not by the above detailed descriptions.

Exemplary embodiments of the present invention, described herein, include various operations. These operations may be performed by hardware polarizations, software, firmware, or a combination thereof. As used herein, the term “coupled to” may mean coupled directly or indirectly through one or more intervening polarizations. Any of the signals provided over various buses described herein may be time multiplexed with other signals and provided over one or more common buses. Additionally, the interconnection between circuit polarizations or blocks may be shown as buses or as single signal lines. Each of the buses may alternatively be one or more single signal lines and each of the single signal lines may alternatively be buses.

Exemplary embodiments of the present disclosure may comprise any one or more of the novel features described herein, including in the Detailed Description, and/or shown in the drawings. As used herein, “at least one,” “one or more” and “and/or” are open-ended expressions that are both conjunctive and disjunctive in operation. For example, each of the expressions “at least one of A, B and C,” “at least one of A, B, or C,” “one or more of A, B, and C,” “one or more of A, B, or C” and “A, B, and/or C” means A alone, B alone, C alone, A and B together, A and C together, B and C together, or A, B and C together. It is to be noted that the term “a” or “an” entity refers to one or more of that entity. As such, the terms “a” (or “an”), “one or more” and “at least one” can be used interchangeably herein.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A low noise block (LNB) integrated circuit (IC) in an integrated chip, comprising:
a first pin and a second pin, receiving first and second polarization signals respectively;
a first low noise amplification (LNA) circuit, coupled to the first pin for receiving the first polarization signal from an antenna, partially removing image signal from the first polarization signal, and generating a first amplified and filtered polarization signal;
a second low noise amplification circuit, coupled to the second pin for receiving the second polarization signal from the antenna, partially removing image signal from the second polarization signal, and generating a second amplified and filtered polarization signal;
a RF path selector, coupled to the first and second amplification circuits, and directing the path of the first and second amplified and filtered polarization signals; and
a signal downconverter, coupled between the RF path selector and a first output pin.

2. The LNB IC of claim 1, wherein each of the first and second low noise amplification circuits comprises a low noise amplifier and an image rejection filter, wherein the image rejection filter is configured to partially remove the image signal from the received first and second polarization signals.

3. The LNB IC (10) of claim 2, wherein the low noise amplifier is a two-stage low noise amplifier comprising an input stage and an output stage, and wherein the image rejection filter is coupled between the input and output stages of the two-stage noise amplifier.

4. The LNB IC of claim 1, wherein each of the first and second low noise amplification circuits comprises an ESD circuit and silicon inductors or wire-bonding inductors.

5. The LNB IC of claim 1, further comprising:
a third pin, connected to an external power supply, and
a fourth pin and a fifth pin, coupled to an external clock.

6. The LNB IC of claim 1, further comprising:
a sixth pin; and
a control circuit, coupled to the third pin, controlling a first amplifier coupled between the first polarization signal and the first pin and a second amplifier coupled between the second polarization signal and the second pin.

7. The LNB IC of claim 1, wherein the signal downconverter is configured to frequency-convert an output of the RF path selector by mixing the first or second amplified and filtered polarization signal with a local oscillation signal and to further remove the image signal from the first and second polarization signals.

8. The LNB IC of claim 7, wherein the signal downconverter comprises:
an image rejection mixer, receiving the first or second amplified and filtered polarization signal from the RF path selector and mixing the first or second amplified and filtered polarization signal based on a local oscillation signal generated by a local oscillator for generating a first intermediate frequency (IF) signal and a second IF signal;
a first IF amplifier, coupled to the image rejection mixer;
an IF filter, coupled to the IF amplifier, and re-combining the first and second IF signals for further removing the image signal from the received first and second polarization signals; and
a second IF amplifier, coupled to the IF filter and amplifying the output of the IF filter.

9. The LNB IC of claim 8, wherein the signal downconverter comprises:
a frequency detector, coupled to the local oscillator, monitoring the received first and second polarization signals as to detect the presence of a signal at a specific frequency, and transmitting a control signal to the local oscillator as to select the local oscillation frequency used for mixing the first or second amplified and filtered polarization signal based on the detection of the presence of the signal at the specific frequency.

10. The LNB IC of claim 1, wherein the RF path selector is configured to output the first or second amplified and filtered polarization signal to the first output pin thru Nth output pin independently.

11. The LNB IC of claim 10, wherein the signal downconverter comprises a plurality of signal downconverters, coupled between the RF path selector and the first thru the Nth output pins.

12. A low noise block (LNB) converter, comprising:
a circuit board; and
a LNB integrated circuit (IC), disposed on the circuit board, converting a first polarized signal and a second polarized signal to an intermediate frequency (IF) signal, wherein the LNB IC comprises:
a first on-chip low noise amplification circuit, coupled to a first pin for receiving the first polarized signal from an antenna, partially removing image signal from the first polarized signal, and generating a first amplified and filtered polarized signal;
a second on-chip low noise amplification circuit, coupled to a second pin for receiving the second polarized signal from the antenna, partially removing image signal from the second polarized signal, and generating a second amplified and filtered polarized signal;
a RF path selector, coupled to the first and second amplification circuits, and directing the path of the first and second amplified and filtered polarization signals; and
a signal downconverter, coupled between the RF path selector and a first output pin for receiving the first or second amplified and filtered polarization signal, and generating the intermediated frequency signal to the first output pin.

13. The LNB converter of claim 12, wherein each of the first and second low noise amplification circuits comprises a low noise amplifier and an image rejection filter, wherein the image rejection filter is configured to partially remove the image signal from the received first and second polarization signals.

14. The LNB converter of claim 12, wherein the signal downconverter comprises:
an image rejection mixer, receiving the first or second amplified and filtered polarization signal from the RF path selector and mixing the first or second amplified and filtered polarization signal based on a local oscillation signal generated by a local oscillator for generating a first intermediate frequency (IF) signal and a second IF signal;
a first IF amplifier, coupled to the image rejection mixer;
an IF filter, coupled to the first IF amplifier, and re-combining the first and second IF signals for further removing the image signal from the received first and second polarization signal; and
a second IF amplifier, coupled to the IF filter and amplifying the output of the IF filter.

15. The LNB converter of claim 12, further comprising:
a first off-chip amplifier, disposed on the circuit board, and coupled between the antenna and the first pin of the LNB IC to amplify the first polarization signal; and
a second off-chip amplifier, disposed on the circuit board, and coupled between the antenna and the second pin of the LNB IC to amplify the second polarization signal.

16. The LNB converter of claim 12, further comprising:
an external power supply, disposed on the circuit board, and coupled to a third pin of the LNB converter; and
an external crystal, disposed on the circuit board, and coupled to a fourth pin and a fifth pin of the LNB converter.

17. The LNB converter of claim 15, wherein the LNB IC further comprising:
a sixth pin, coupled to the first off-chip amplifier and the second off-chip amplifier;
a control circuit, coupled to the sixth pin, controlling the first off-chip amplifier coupled between the first polarization signal and the first pin and the second off-chip amplifier coupled between the second polarization signal and the second pin.

18. A satellite receiving system, comprising:
an antenna;
a set-top-box;
a low noise block (LNB) converter integrated on a chip, coupled between the antenna and the set-top-box, converting a vertical polarized signal and a horizontal polarized signal received from the antenna to an intermediate frequency signal, wherein the LNB converter comprises:
a first low noise amplification circuit, coupled to the first pin to receive the vertical polarized signal from the antenna, partially removing image signal from the vertical polarized signal, and generating an amplified and filtered vertical polarized signal;
a second low noise amplification circuit, coupled to a second pin to receive the horizontal polarized signal from the antenna, partially removing image signal from the horizontal polarized signal, and generating an amplified and filtered horizontal polarized signal;
a RF path selector, coupled to the first and second amplification circuits, and directing the path of the first and second amplified and filtered polarization signals; and
a signal downconverter, coupled between the RF path selector and a first output pin to receive the first or second amplified and filtered polarization signal and generate the intermediated frequency signal to the set-top-box.

19. The satellite receiving system of claim 18, wherein each of the first and second low noise amplification circuits comprises a low noise amplifier and an image rejection filter, wherein the image rejection filter is configured to partially remove the image signal from the received vertical and horizontal polarized signals.

20. The satellite receiving system of claim 19, wherein the signal downconverter comprises a complex mixer and filter, and the complex mixer and filter is configured to attenuate the image signal of the RF signal received from the first and second low noise amplification circuits.
